(19) United States
(12) Patent Application Publication
(10) Pub. No.: US 2007/0054432 A1
(43) Pub. Date: Mar. 8, 2007

(54) METHOD FOR PRODUCING A STRUCTURE WITH A LOW ASPECT RATIO

(75) Inventor: Hans-Peter Moll, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: QIMONDA AG, Munich (DE)

(21) Appl. No.: 11/466,275

(22) Filed: Aug. 22, 2006

(30) Foreign Application Priority Data
Aug. 22, 2005 (DE) 10 2005 039 667.4

(51) Int. Cl. H01L 21/00

(52) U.S. Cl. 438/42

(57) ABSTRACT

A method for producing a structure with a low aspect ratio is disclosed. In one embodiment, an initial structure is formed conformally within an opening in a semiconductor substrate, the opening being filled with a sacrificial structure, and the initial structure being removed outside the opening. By removing a part of the initial structure in the sidewall region between the sacrificial structure and the semiconductor substrate, a structure with a low aspect ratio is provided.

### CROSS-REFERENCE TO RELATED APPLICATIONS

This Utility Patent Application claims priority to German Patent Application No. DE 10 2005 039.667.4 filed on Aug. 22, 2005, which is incorporated herein by reference.

### BACKGROUND

The invention provides a method for producing a structure with a low aspect ratio, and a method for producing an SSBS (single sided buried strap) for a trench DRAM memory cell based on the structure with a low aspect ratio.

Structures with a low aspect ratio serve for example as an insulating covering layer for trench capacitances or else as structures for masking parts of a bottom region within trench openings. In the latter case, such structures with a low aspect ratio are important for example when forming an SSBS. In this case, it is necessary that a filling structure that does not completely fill the trench is only partly covered, in order thus to remove material of the filling structure only in the uncovered partial region in a subsequent etchingprocess. In this case, in a known manner the procedure is such that firstly a bottom region and sidewalls within the remaining opening of the trenches and a surface of a semiconductor substrate outside the openings are covered with a layer made of amorphous silicon. By oblique implantation of dopants, dopants are then introduced only into those regions of the structure which are not shaded by one of two mutually opposite sidewalls at the bottom of the opening. The non-doped regions at the bottom can be removed in a subsequent process by an etch that is selective with respect to the dopant concentration of the amorphous silicon, thereby providing the desired mask which covers only a portion at the bottom of the opening. However, this known method leads to problems in the context of the miniaturization of semiconductor memory cells and thus the reduction of the diameter of the trenches or the openings.

A reduction of the trench widths cannot be counteracted arbitrarily by a reduction of the implantation angle, that is to say the angular deviation relative to a normal to the surface, in order to obtain the reduced feature sizes, since, at very small implantation angles, on account of the thickness of the amorphous silicon layer at the other of the two sidewalls, the dopants no longer pass into a corner region of the amorphous silicon adjoining the bottom with respect to the other sidewall. It acts as self-shading by the amorphous silicon layer formed on the other sidewall. A subsequent etch of the amorphous silicon results not only in the desired opening in the bottom region shaded by one sidewall, but in an additional, undesirable opening in the opposite corner region. Such a mask made of amorphous silicon is not suitable for further embodiment of the SSBS.

In the context of reducing the trench diameters in the transition from one technology to a subsequent technology with smaller feature sizes, it may be the case that the implantation angle for forming the mask during the SSBS processing cannot be maintained since the shading by sidewalls during the implantation becomes too great and the mask to be formed at the bottom can no longer be provided with the desired lateral dimensions.

For these and other reasons, there is a need for the present invention.

### SUMMARY

The invention provides a method for producing a structure with a low aspect ratio. In one embodiment, an initial structure is formed conformally within an opening in a semiconductor substrate, the opening being filled with a sacrificial structure, and the initial structure being removed outside the opening. By removing a part of the initial structure in the sidewall region between the sacrificial structure and the semiconductor substrate, a structure with a low aspect ratio is provided.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A to C′ illustrate schematic cross-sectional views of process stages during a known method for producing a structure that only partly covers a bottom region of an opening.

FIG. 2 illustrates a schematic cross-sectional view for illustrating a first possibility for scaling of the structure in accordance with a known method.

FIG. 3 illustrates a schematic cross-sectional view for illustrating a second possibility for scaling of the structure in accordance with a known method.

FIG. 4 illustrates a schematic cross-sectional view for illustrating a third possibility for scaling of the structure in accordance with a known method.

FIG. 5 illustrates a schematic cross-sectional view for illustrating a fourth possibility for scaling of the structure in accordance with a known method.

FIG. 6 illustrates a schematic cross-sectional view for illustrating a fifth possibility for scaling of the structure in accordance with a known method.

FIGS. 7A-E illustrate schematic cross-sectional views for illustrating various process stages during the formation of the structure with a low aspect ratio according to the invention.

FIGS. 8 to 10 illustrate schematic cross-sectional views for illustrating process stages of various further embodiments.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The invention provides a method for producing a structure with a low aspect ratio and a method for producing an SSBS for a trench DRAM memory cell based on the structure with a low aspect ratio by means of which the problems described above can be avoided.

In one embodiment, the invention provides a method for producing a structure with a low aspect ratio, including providing a semiconductor substrate having openings reaching from a surface into the semiconductor substrate, the semiconductor substrate being covered with an initial structure both within the openings at sidewalls and a bottom region and outside the openings at the surface, forming a sacrificial structure that fills the openings and covers the surface outside the openings, removing the parts of the sacrificial structure which lie outside the openings, forming the structure with a low aspect ratio from the initial structure by removing part of the initial structure adjoining the sidewalls within the openings, the aspect ratio being defined as the ratio of a height of sidewalls of the structure and a width of the openings, and removing the sacrificial structure.

In one embodiment, the semiconductor substrate is formed from silicon or germanium or a III-V semiconductor material such as gallium arsenide. The openings may for example involve a part of a trench, in which case the trench may already have been partly filled and the opening to the surface of the semiconductor substrate remains. A capacitor of a trench DRAM memory cell, for example, may be formed in the filled lower part of the trench. The semiconductor substrate may, for its part, likewise have been preprocessed, so that a trench capacitor or further structures, for instance, have been formed alongside the openings and the initial structure by means of further method. The initial structure is formed for example as a conformally deposited layer and uniformly covers the semiconductor substrate including the surfaces within the openings. In one embodiment, production methods that are dependent on the material of the initial structure, such as PVD (physical vapor deposition, for instance vaporization, sputtering), CVD (chemical vapor deposition) or else ECD (electrochemical deposition), serve for forming the initial structure. The sacrificial structure has a material composition that deviates from the initial structure such that the initial structure can be etched relative to the sacrificial structure, and vice versa. After the removal of the parts of the sacrificial structure and of the initial structure which lie outside the openings, these structures have remained only within the openings. The removal of part of the initial structure which adjoins the sidewalls within the openings is effected by etching proceeding from the surface along the sidewalls into the opening. A time-coordinated etching process, for instance, is appropriate in this case since the initial structure is not intended to be removed at the bottom of the opening. The removal of the sacrificial structure is effected by etching, the structure with a low aspect ratio formed beneath the sacrificial structure not being attacked or only being attacked to a negligible extent. The structure with a low aspect ratio has, in comparison with the initial structure prior to the sidewall etch, an aspect ratio that is lower depending on a depth of the opening.

In one embodiment, the initial structure is removed in the openings essentially apart from a part that covers the bottom region. Ideally, the structure has a uniform thickness in the bottom region, that is to say that the etch of the initial structure in the region of the sidewalls stops upon reaching a transition between the sacrificial structure and the underlying part of the initial structure. Since the structure is intended initially to completely cover the bottom region, an etching stop layer deviating from the initial structure is not available and the etch of the initial structure at the sidewalls is effected in a time-coordinated manner within the initial structure. In this case, on account of a safety window during the etch, the structure will be formed such that it is higher in bottom regions adjoining the sidewalls than in the bottom region formed beneath the sacrificial structure. However, it is equally possible for the structure, during an undercut etch, to be formed such that it is slightly thinner in the bottom region adjoining the sidewalls than in the bottom region lying beneath the sacrificial structure. The controllability of the etch of the initial structure is crucial for this.

A further embodiment includes introducing dopants into the structure by implanting the dopants at an angle tilted with respect to the normal to the surface, and providing a structure that only partly covers the bottom region by removing the parts of the structure which were shaded by the sidewalls during the implantation.

The lateral extent of the shaded region of the structure at the bottom of the opening results from the height of the sidewalls multiplied by the tangent of the implantation angle. The removal of the parts of the structure which were shaded by the sidewalls during implantation into the opening can be carried out in a simple manner if it is possible to use an etching solution which removes only the regions of the structure that contain no dopants. In this case, a varying dopant concentration of the structure provides the etching selectivity. Such an etching selectivity may be obtained for example if the structure is formed from non-doped amorphous or polycrystalline silicon and is partly doped for example with boron at the bottom by implantation that is tilted with respect to the normal to the surface. An ammonia etch, for example, is appropriate in this case as the etching solution.

In one embodiment, the tilted angle lies within the range of 10° to 30°. It is thereby possible to create structures which are only partly formed at the bottom and whose lateral dimensions are suitable for forming semiconductor components having minimum feature sizes of less than 100 nm.

In a further embodiment, the structure is formed with a thickness within the range of 5 to 20 nm. Reducing the thickness of the structure makes it possible, on the one hand, to reduce self-shading effects and thus to effect doping in the corner region of the bottom, but on the other hand reducing the thickness leads to a more complex process implementation when removing the initial structure in the sidewall region. When forming very thin structures there is likewise the risk of pinholes being produced.

It is preferred to remove the sacrificial structure and the initial structure on the surface outside the openings by an RIE (reactive ion etching) or CMP (chemical mechanical polishing) process by planarization. Only parts of the initial structure and of the sacrificial structure formed within the openings remain after this planarization process.

In one embodiment, the sacrificial structure is formed from an oxide and the structure is formed from amorphous or polycrystalline silicon. In the case of a semiconductor substrate made of silicon, a suitable oxide is, in particular, SiO₂. A selective etch of the amorphous or polycrystalline silicon relative to the sacrificial structure can thereby be obtained for example by means of an ammonia solution.

In an alternative embodiment, the sacrificial structure is formed from amorphous or polycrystalline silicon and the structure is formed from an oxide. By selectively etching the oxide with respect to the sacrificial structure, e.g., using hydrofluoric acid, it is possible to provide the structure made from oxide with a low aspect ratio. Such a structure may serve for example as an insulating isolating layer between different planes within a trench or as an insulating covering layer.

In a further embodiment, parts of the initial structure which lie outside the openings are also removed in the course of removing the parts of the sacrificial structure which lie outside the openings.

As an alternative to this, the parts of the initial structure which lie outside the openings may be removed in the course of forming the structure with a low aspect ratio. In this case, the initial structure may serve as a stop during the removal of the parts of the sacrificial structure which lie outside the openings.

In accordance with a further embodiment the sacrificial structure is partly removed within the openings prior to forming the structure with a low aspect ratio.

In accordance with one embodiment, the oxide of the sacrificial structure is formed from ozone-TEOS (TEOS: tetraethylorthosilane) or spin-on glass.

According to a further embodiment, the initial structure is removed by means of a dry etching process.

In accordance with a further embodiment, a blocking mask is at least partly applied to uncovered surface regions prior to removing the parts of the sacrificial structure which lie outside the openings. It is thereby possible to protect in particular surface regions with alignment structures present against further process with material removal.

A method for producing a single sided buried strap for a trench DRAM memory cell is based on the structure made of amorphous or polycrystalline silicon according to the invention and the sacrificial structure formed from oxide. In this case, the structure is doped by oblique implantation in partial regions at the bottom and is selectively etched in a subsequent process, with the result that a structure that only partly covers the bottom of the opening is maintained. The structure produced in this way serves, in a subsequent process, as an etching mask during the removal of parts of a trench filling which lie beneath the uncovered bottom region. Subsequent method serve for completing the single sided buried strap in the region of a semiconductor body which adjoins the etched region of the trench filling.

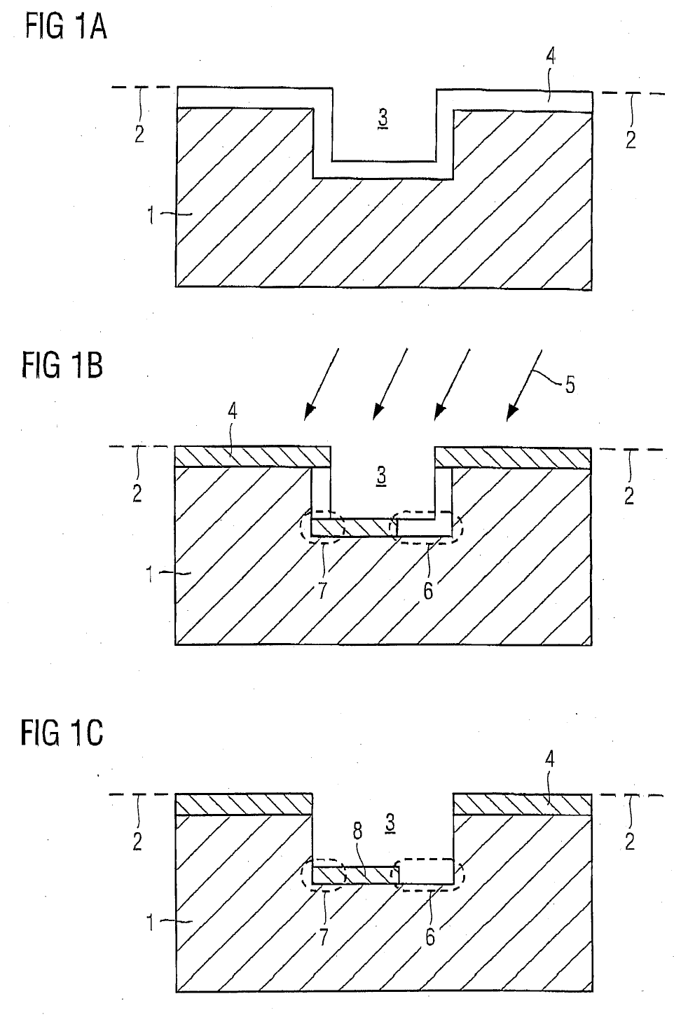

In order to afford a better understanding of the invention, the text below describes a method for producing a structure that is to be formed only partly in a bottom region of an opening, and specifies possibilities for the scaling of the structure in the transition from one technology to a subsequent technology with smaller feature sizes. The cross-sectional views illustrated in the descriptions of FIGS. 1 to 6 below illustrate method process during the formation of a structure that partly covers the bottom region of an opening during the production of the SSBS for a trench DRAM memory cell.

FIG. 1A illustrates a schematic cross-sectional view of a semiconductor substrate 1, into which an opening 3 extends from a surface 2. The semiconductor substrate 1 is covered with a conformally formed initial structure 4 at the surface and at the sidewalls and in a bottom region of the opening 3. Structures formed in the semiconductor substrate 1 in preceding method are not illustrated for the sake of clarity. By way of example, the initial structure 4 formed in the bottom region of the opening 3 covers a partly filled trench. The partly filled trench is formed for example as a trench capacitor of a trench DRAM memory cell and is intended to be connected to a selection transistor via an SSBS in further method process.

FIG. 1B illustrates a schematic cross-sectional view of the semiconductor substrate 1 after an implantation of dopants into the initial structure 4 that is effected along the implantation direction 5. On account of the oblique implantation, no dopants are introduced in that part of the initial structure 4 which lies in the bottom region 6 shaded by a sidewall. In the corner region 7 opposite the shading sidewall, the dopants penetrate into the initial material 4. Doped regions are resistant to a subsequent etch, whereas non-doped regions are attacked and removed.

FIG. 1C illustrates a schematic cross-sectional view of the semiconductor substrate 1 after removal of those parts-illustrated in FIG. 1B—of the initial structure 4 into which no dopants were introduced during the implantation. This results in the structure 8 that only partly covers the bottom region of the opening 3 and is produced from the initial structure 4. It is thus possible to continue in further method with the processing of the SSBS.

FIG. 1B′ illustrates a cross-sectional view of the semiconductor substrate 1 similar to FIG. 1B, the cross-sectional view in FIG. 1B′ differing from the cross-sectional view in FIG. 1B merely by the fact that the implantation of the dopants was effected along a different implantation direction 5′. The implantation direction 5′ in FIG. 1B′ is at a smaller tilting angle with respect to the normal to the surface in comparison with the tilting angle of the implantation direction 5 indicated. On account of this smaller tilting angle, no dopants or too few dopants for etching resistance (hereinafter no dopants will be assumed for simplification) are introduced into the corner region 7 during the implantation. On the other hand, the smaller tilting angle enables smaller lateral dimensions of the shaded bottom region 6 and thus smaller feature sizes.

After the removal of those parts of the initial structure 4 in FIG. 1B′ into which no dopants were introduced by the implantation, the result is the cross-sectional view of the semiconductor substrate 1 illustrated in FIG. 1C′. On account of the absent dopants in the corner region, the structure 8 is also removed in this region, so that the structure no longer adjoins any of the two sidewalls at the bottom of the opening 3. Such a structure 8 is not suitable for further processing of the SSBS.

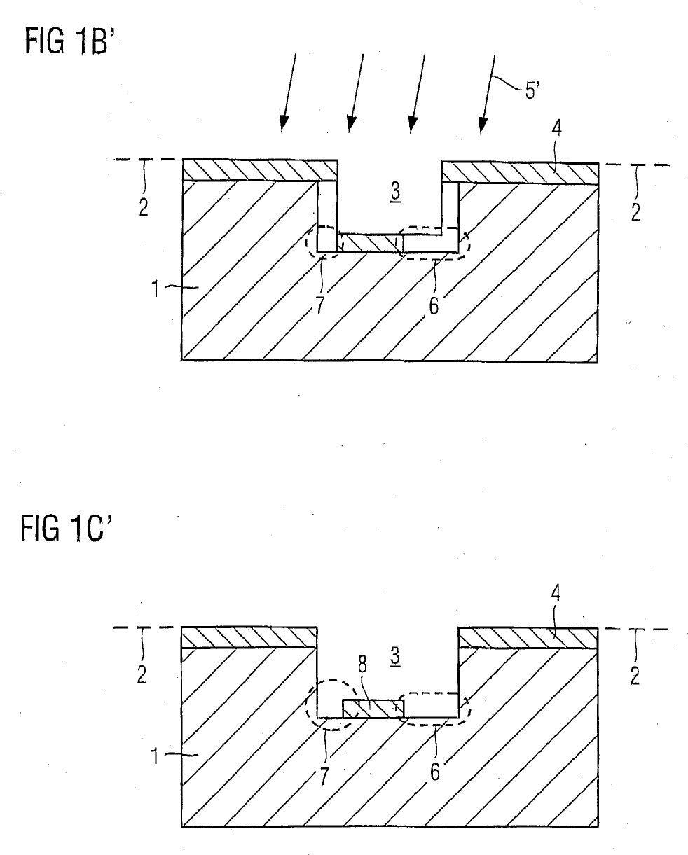

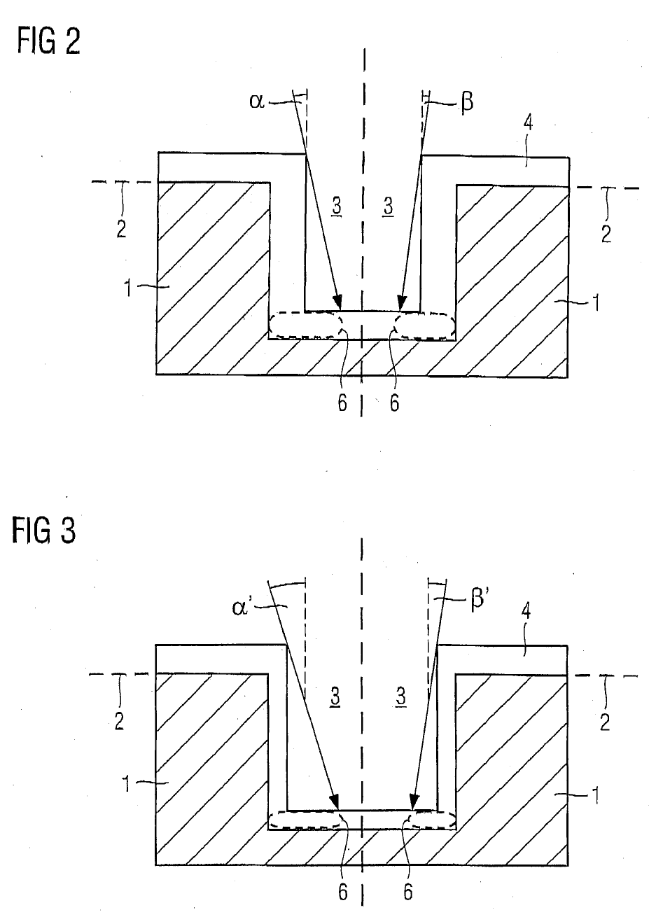

FIG. 2 illustrates a schematic cross-sectional view of a semiconductor substrate 1 during the process stage of the oblique implantation of dopants into an initial structure 4 in an opening 3 for producing a structure that only covers a bottom region. In this case, FIG. 2 illustrates a first scaling possibility, in which case, in the left-hand one of the two partial Figures separated by an interrupted vertical line, the implantation is effected at an implantation angle α with respect to the normal to the surface. A lateral extent of the bottom region 6 shaded by the sidewall is defined by the implantation angle α, the thickness of the initial structure 4 at the sidewall and the height of the sidewall. The right-hand partial Figure illustrates the process stage corresponding to the left-hand partial Figure for a smaller minimum feature size, that is to say for instance after a transition from one memory generation to a subsequent memory generation with a smaller structural width. Consequently, in FIG. 2 and in FIGS. 3 to 6 as well, the left-hand partial Figure illustrates the process stage before the structural miniaturization and the right-hand partial Figure correspondingly illustrates the process stage after the structural miniaturization. If, when reducing the structural width, the thickness of the initial structure is retained as shown, then it is necessary to reduce the implantation angle β in comparison with the implantation angle α in order not to exceed the required lateral extent of the bottom region 6 shaded by the sidewall after the structural miniaturization. However, during a subsequent removal of non-doped regions of the initial structure 4, this may lead to the undesirable etching in the corner region 7 not illustrated (in this respect, cf. the corner region 7 in FIG. 1C′).

The cross-sectional view of the semiconductor substrate 1 that is illustrated in FIG. 3 and serves for elucidating a second scaling possibility differs from that in FIG. 2 merely by the fact that the thickness of the initial structure 4 is reduced in the opening 3. Accordingly, in order to obtain the same lateral extent of the bottom region 6 shaded by the sidewall as in FIG. 2, it is possible to use a larger implantation angle α′ in comparison with the implantation angle α from FIG. 2 in the left-hand partial Figure. The same holds true after the structural miniaturization in the right-hand partial Figure for an implantation angle β′ compared with the implantation angle β from FIG. 2. On account of the now increased implantation angle, the risk of a lack of implantation in the corner region 7 (see FIG. 1C′) is reduced, but they continue to exist depending on the dimensions of the opening 3 and initial structure 4. There is likewise the risk of pinholes being formed on account of the reduced thickness of the initial structure 4 within the opening 3.

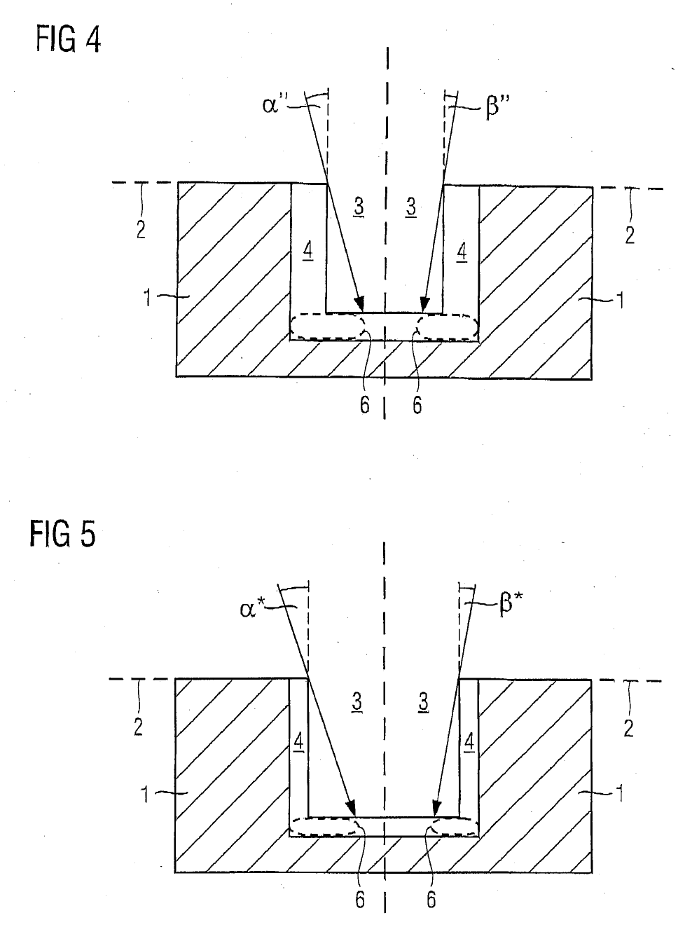

FIG. 4 likewise specifies a cross-sectional view of the semiconductor substrate 1 for elucidating a third scaling possibility for forming a structure that only partly covers the bottom region in the opening 3. The initial structure 4 differs from the initial structure 4 illustrated in FIG. 2 by the fact that it is removed prior to implantation of the dopants into the initial structure 4 on the surface of the semiconductor substrate 2, so that the initial structure 4 remains only in the opening 3. The height of the initial structure 4 is thereby reduced, resulting in a reduction of the shading by the sidewall during the implantation. It is thus possible to increase the implantation angle α″ in comparison with the implantation angle α from FIG. 2 whilst maintaining the lateral dimensioning of the shaded bottom region 6. The same correspondingly holds true for the implantation angle β″ after scaling has been effected in comparison with the corresponding angle β of the right-hand partial Figure from FIG. 2. The angle β″ required for obtaining the desired feature size may nevertheless be too small to introduce dopants into the corner region 7 (cf. FIG. 1B), which would lead to the undesirable structure illustrated in FIG. 1C′. On the basis of the removal of the initial structure 4 on the surface 2 that is usually embodied as CMP planarization, residues of a CMP grinding material may remain, which critically impairs the process yield for instance during the production of an SSBS.

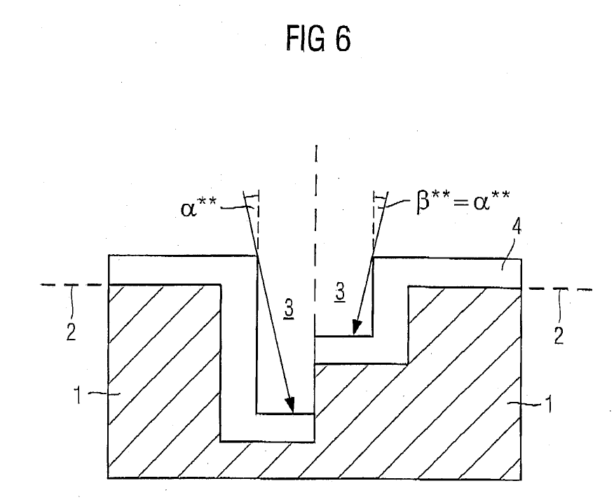

FIG. 5 illustrates a further cross-sectional view of the semiconductor substrate 1 for illustrating a fourth scaling possibility during the production of a structure that only covers a part of the bottom region, proceeding from the initial structure 4. In this case, the initial structure 4 differs from the initial structure 4 illustrated in FIG. 4 merely by the fact that it is thinner. Consequently, it is possible to increase the implantation angle α* and also the implantation angle β* used after the scaling in comparison with the corresponding implantation angles α″ and β″ in FIG. 4. The risk of process impairment by residues of CMP grinding material still remains, however.

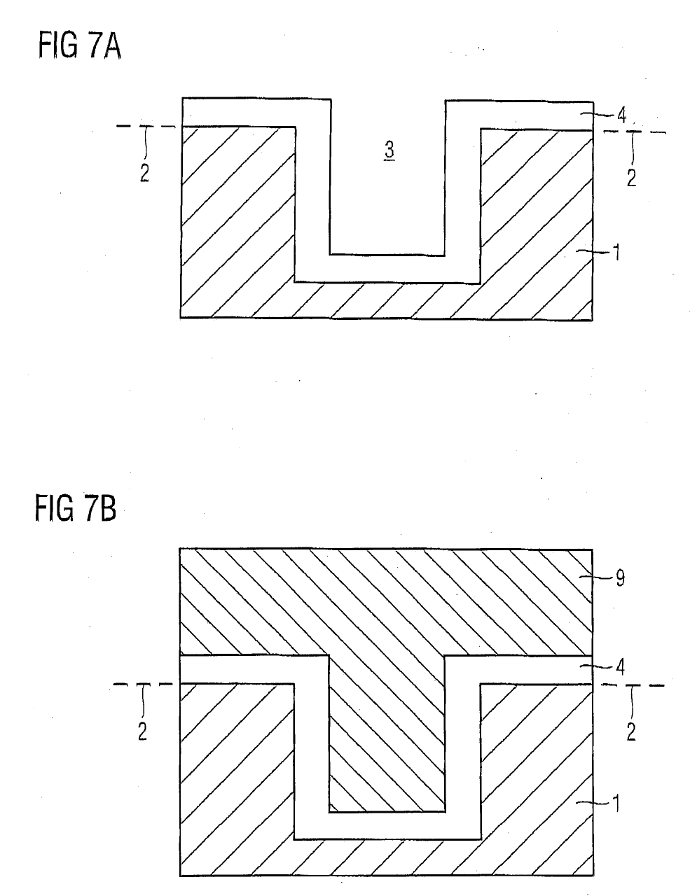

FIG. 6 illustrates a schematic cross-sectional view for illustrating a fifth scaling possibility during the formation of a structure that only partly covers the bottom region of the opening 3 proceeding from the initial structure 4. In this case, in order to maintain the angle α** in the course of scaling, i.e. β**=α**, the opening 3 after scaling (right-hand partial Figure) is formed with a reduced depth in comparison with the opening 3 prior to scaling (left-hand partial Figure).

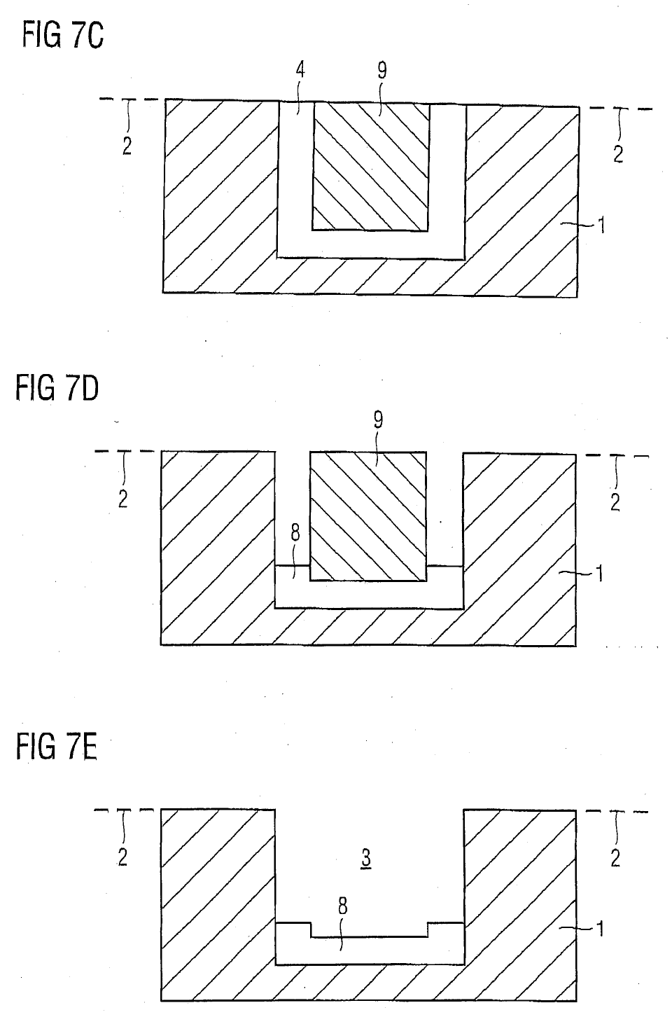

FIG. 7 illustrates schematic cross-sectional views of successive process stages in the implementation of a method according to the invention for providing the structure 8 with a low aspect ratio within the opening 3.

The cross-sectional view in FIG. 7A illustrates the semiconductor body 1 with an opening 3 and a conformally formed initial structure 4. The opening 3 is filled with a sacrificial structure 9, as illustrated in FIG. 7B, the sacrificial structure additionally being formed above the opening 3 and above the parts of the initial structure 4 which lie outside the opening 3.

The sacrificial structure 9 and the part of the initial structure 4 which lies outside the opening 3 are removed, as illustrated in FIG. 7C. A CMP planarization process, for example, is suitable for this purpose. The aspect ratio of the initial structure 4 is now determined by the width of the opening 3 and by the height of the sidewalls within the opening 3.

In order to reduce the aspect ratio of the initial structure 4, a part of the initial structure 4 is removed along the sidewalls in the opening 3 by etching, as illustrated in FIG. 7D. This etch is effected selectively with respect to the sacrificial structure 9 and with respect to the adjoining semiconductor substrate 1. The semiconductor substrate 1 may, for its part, have a liner layer which adjoins the initial structure 4 and provides the required etching selectivity. The etch of the initial structure 4 in the sidewall region is stopped before reaching that depth to which the sacrificial structure 9 has been formed. Consequently, the structure 8 with a low aspect ratio produced from the initial structure 4 completely covers the bottom region of the opening 3. On account of the prematurely stopped etch, the structure has been formed such that it is higher in the sidewall region than in the bottom region lying beneath the sacrificial structure 9.

FIG. 7E illustrates a schematic cross-sectional view of a process stage during the method according to the invention for forming the structure 8 with a low aspect ratio after the removal of the sacrificial structure 9.

The removal of the sacrificial structure 9 may be followed by a dopant implantation in order to remove parts of the structure 8 in the bottom region and to continue with the processing of an SSBS.

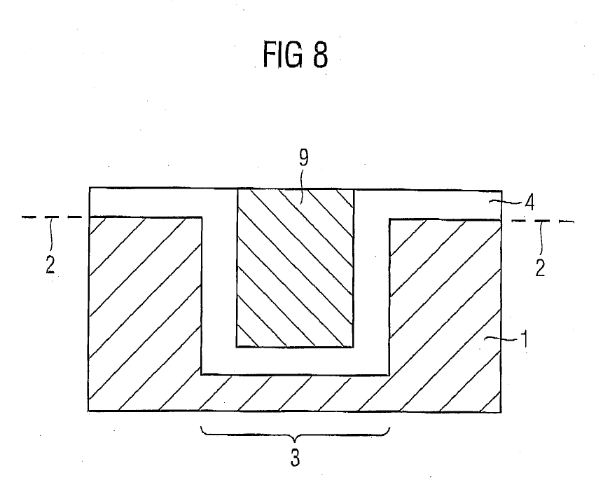

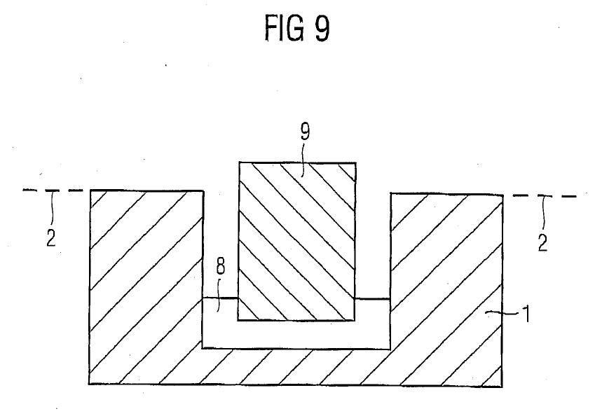

FIG. 8 illustrates a schematic cross-sectional view of an alternative process stage to FIG. 7C. In this case, the initial structure 4 is used as a stop during the removal of the sacrificial structure 9 outside the opening 3. In this embodiment, the parts of the initial structure 4 which lie outside the opening 3 can be removed in the later process for forming the structure 8 with a low aspect ratio. This is illustrated by way of example in the schematic cross-sectional view in FIG. 9.

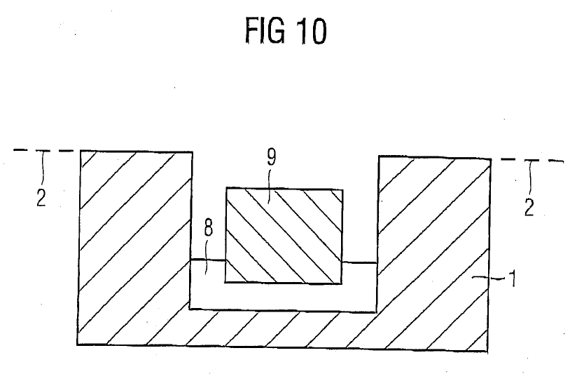

The schematic cross-sectional view illustrated in FIG. 10 illustrates an alternative embodiment to the process stage of FIG. 7D. In this case, the sacrificial structure 9 is partly removed within the opening 3 prior to the formation of the structure 8 with a low aspect ratio. This may be effected after the process stage of FIG. 7C or FIG. 8 and has the result that the process of removing the initial structure 4 along the sidewalls in the opening 3 can be effected more precisely.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a structure with a low aspect ratio, comprising:
providing a semiconductor substrate having openings reaching from a surface into the semiconductor substrate, the semiconductor substrate being covered with an initial structure;
forming a sacrificial structure that fills the openings and covers the surface outside the openings;
removing the parts of the sacrificial structure which lie outside the openings; and
forming a structure with a low aspect ratio from the initial structure by removing part of the initial structure adjoining the sidewalls within the openings, the aspect ratio being defined as the ratio of a height of sidewalls of the structure and a width of the openings.

2. The method as claimed in claim 1, wherein the initial structure is removed in the openings essentially apart from a part that covers the bottom region.

3 . The method as claimed in claim 1, comprising:
introducing dopants into the structure by implanting the dopants at an angle tilted with respect to the normal to the surface; and
providing a structure that only partly covers the bottom region by removing the parts of the structure which were shaded by the sidewalls during the implantation.

4. The method as claimed in claim 3, wherein the tilted angle lies within the range of 10° to 30°.

5. The method as claimed in claim 1, wherein the structure is formed with a thickness within the range of 5 to 20 nm.

6. The method as claimed in claim 1, wherein parts of the initial structure which lie outside the openings are also removed in the course of removing the parts of the sacrificial structure which lie outside the openings.

7. The method as claimed in claim 1, wherein parts of the initial structure which lie outside the openings are also removed in the course of forming the structure with a low aspect ratio.

8. The method as claimed in claim 1, wherein the sacrificial structure is partly removed within the openings prior to forming the structure with a low aspect ratio.

9. A method for producing a structure with a low aspect ratio, comprising:
providing a semiconductor substrate having openings reaching from a surface into the semiconductor substrate, the semiconductor substrate being covered with an initial structure both within the openings at sidewalls and a bottom region and outside the openings at the surface;
forming a sacrificial structure that fills the openings and covers the surface outside the openings;
removing the parts of the sacrificial structure which lie outside the openings;
forming a structure with a low aspect ratio from the initial structure by removing part of the initial structure adjoining the sidewalls within the openings, the aspect ratio being defined as the ratio of a height of sidewalls of the structure and a width of the openings; and
removing the sacrificial structure.

10. The method as claimed in claim 9, comprising removing the initial structure in the openings essentially apart from a part that covers the bottom region.

11. The method as claimed in claim 9, comprising:
introducing dopants into the structure by implanting the dopants at an angle tilted with respect to the normal to the surface; and
providing a structure that only partly covers the bottom region by removing the parts of the structure which were shaded by the sidewalls during the implantation.

12. The method as claimed in claim 11, wherein the tilted angle lies within the range of 10° to 30°.

13. The method as claimed in claim 9, comprising forming the structure with a thickness within the range of 5 to 20 nm.

14. The method as claimed in claim 9, comprising removing the sacrificial structure on the surface outside the openings by means of an RIE or CMP step by planarization.

15. The method as claimed in claim 9, comprising forming the sacrificial structure from an oxide and the structure is formed from amorphous or polycrystalline silicon.

16. The method as claimed in claim 9, comprising forming the sacrificial structure from amorphous or polycrystalline silicon and the structure is formed from an oxide.

17. The method as claimed in claim 9, wherein parts of the initial structure which lie outside the openings are also removed in the course of removing the parts of the sacrificial structure which lie outside the openings.

18. The method as claimed in claim 9 , wherein parts of the initial structure which lie outside the openings are also removed in the course of forming the structure with a low aspect ratio.

19. The method as claimed in claim 9, wherein the sacrificial structure is partly removed within the openings prior to forming the structure with a low aspect ratio.

20. The method as claimed in claim 15, wherein the oxide is formed as ozone TEOS or spin-on glass.

21. The method as claimed in claim 9, comprising removing the initial structure by means of a dry etching step.

22. The method as claimed in claim 9, comprising applying wherein a blocking mask is at least partly uncovered surface regions prior to removing the parts of the sacrificial structure which lie outside the openings.

23. A method for making a memory cell, comprising:
producing a single sided buried strap for a trench DRAM memory cell based on the structure with a low aspect ratio produced as claimed in claim 7; and
using the structure serving as an etching mask for removing a part of the inner electrode.

27. A system for producing a structure with a low aspect ratio, comprising:
means for providing a semiconductor substrate having openings reaching from a surface into the semiconductor substrate, the semiconductor substrate being covered with an initial structure both within the openings at sidewalls and a bottom region and outside the openings at the surface;
means for forming a sacrificial structure that fills the openings and covers the surface outside the openings;
means for removing the parts of the sacrificial structure which lie outside the openings;
means for forming a structure with a low aspect ratio from the initial structure by removing part of the initial structure adjoining the sidewalls within the openings, the aspect ratio being defined as the ratio of a height of sidewalls of the structure and a width of the openings; and
means for removing the sacrificial structure.
